(19) United States
(12) Patent Application Publication
(10) Pub. No.: US 2014/0160641 A1
(43) Pub. Date: Jun. 12, 2014

(54) ELECTRONIC APPARATUS

(71) Applicant: HTC CORPORATION, Taoyuan County (TW)

(72) Inventors: I-Cheng Chuang, Taoyuan County (TW); Yu-Jing Liao, Taoyuan County (TW); Ying-Yen Cheng, Taoyuan County (TW); Hung-Wen Lin, Taoyuan County (TW)

(73) Assignee: HTC Corporation, Taoyuan County (TW)

(21) Appl. No.: 13/707,599

(22) Filed: Dec. 7, 2012

(51) Int. Cl. H05K 5/00; H05K 5/04

(52) U.S. Cl. CPC H05K 5/0017; H05K 5/04
USPC 361/679.01

(57) ABSTRACT

An electronic apparatus including a housing, a touch-sensing module and a controller is provided. The touch-sensing module is embedded in the housing and includes a plurality of conductive sheets and an insulation material. The insulation material is combined with and electrically insulated from the conductive sheets. The controller is connected to the touch-sensing module, so as to identify the touch-sensing event occurring at the conductive sheets.

### TECHNICAL FIELD

The application relates to an electronic apparatus, and particularly relates to an electronic apparatus with a touch-sensing function.

### BACKGROUND

In the modern information society, people increasingly rely on consumer electronic apparatuses. Apparatuses such as personal digital assistants (PDA), smart phones, or tablet PCs are everywhere in people's daily life. Therefore, the consumer electronic apparatuses have become inseparable from people's life nowadays.

Taking smart phones in the above-mentioned electronic apparatuses as an example, many smart phones now are configured with a touch panel as the input device, instead of using the conventional input devices such as a keyboard or a mouse for the purpose of better convenience, a more compact size, and becoming more humanized.

However, in some of the input elements of the smart phones, such as the elements of power switch or the elements for volume control, mechanical buttons are still used as input elements. Respectively configuring input devices with different operating modes in the electronic products may increase the production cost. In addition, when the buttons are installed on the body, the tolerance of the button sizes or tolerance accumulation during the installation may influence the appearance.

### SUMMARY

The application provides an electronic apparatus adapted for replacing a conventional button with a touch-sensing device.

The application provides an electronic apparatus including a housing, a touch sensing module, and a controller. The touch-sensing module is embedded in the housing and includes a plurality of conductive sheets and an insulation material. The insulation material electrically insulates the conductive sheets and is combined with the conductive sheets. The controller is electrically connected to the touch-sensing module to identify a touch-sensing event on the conductive sheets.

In view of the foregoing, the housing of the electronic apparatus of the application is embedded with the touch-sensing module. The touch-sensing module is formed of the plurality of conductive sheets separated from each other and the insulation material, and the conductive sheets are respectively connected with the controller. When the touch-sensing event occurs, such as the finger of the user approaches or touches the conductive sheets, the controller is capable of identifying the touched position on the conductive sheets, so as to control the electronic apparatus. The conductive sheets of the application are adapted for replacing a button as an input device to keep a preferable appearance of the electronic apparatus.

Several exemplary embodiments accompanied with figures are described in detail below to further describe the application in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the application.

FIG. 1 is a schematic view illustrating an electronic apparatus according to an embodiment of the application.

FIG. 2A is a partially enlarged view of the electronic apparatus of FIG. 1.

FIG. 2B is a schematic view illustrating occurrence of a touch-sensing event in the conductive sheets of FIG. 2A.

FIG. 3 is a schematic view illustrating an electronic apparatus according to another embodiment of the application.

FIG. 4 is a partially enlarged view of the electronic apparatus of FIG. 3.

### DETAILED DESCRIPTION OF DISCLOSED EMBODIMENTS

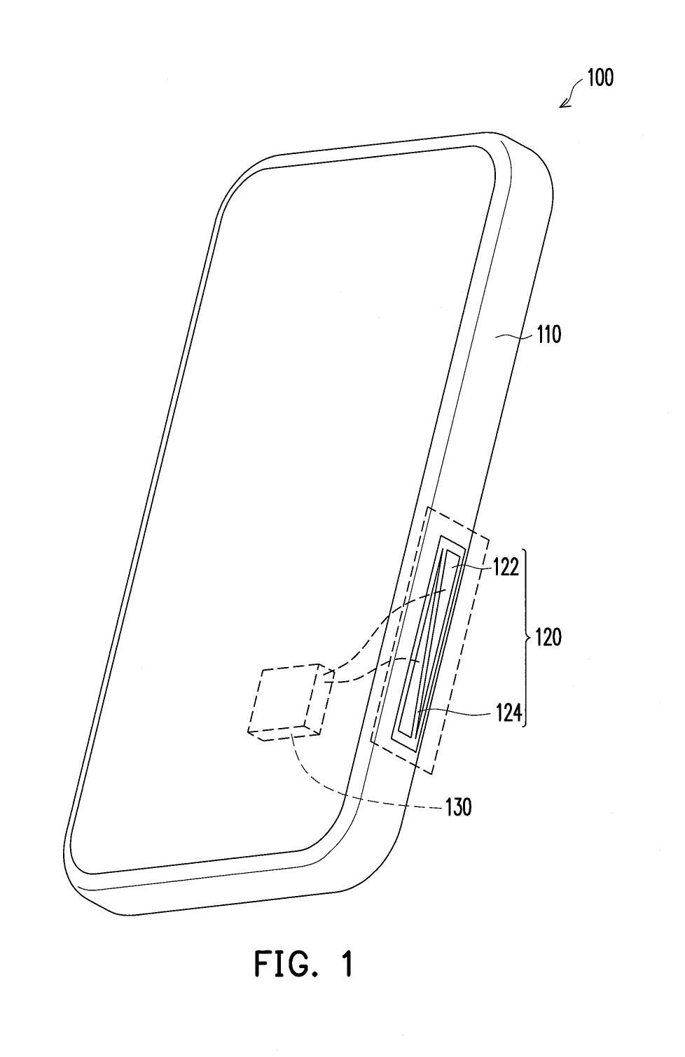

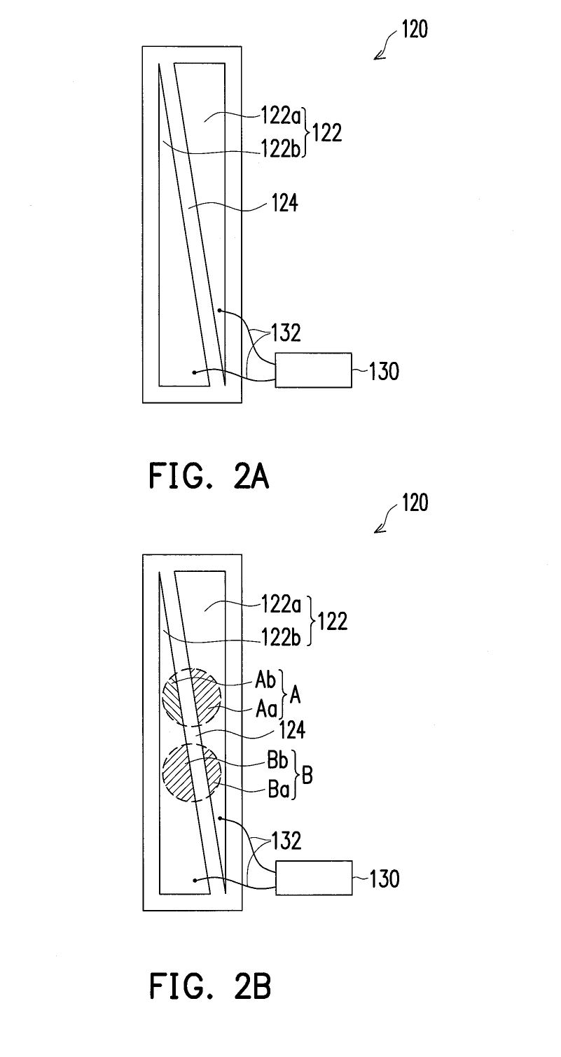

FIG. 1 is a schematic view illustrating an electronic apparatus according to an embodiment of the application. FIG. 2A is a partially enlarged view of the electronic apparatus of FIG. 1. Referring to FIGS. 1 and 2A, an electronic apparatus 100 of this embodiment includes a housing 110, a touch-sensing module 120, and a controller 130. The touch-sensing module 120 is embedded in the housing 110 and includes a plurality of conductive sheets 122 and an insulation material 124. The insulation material 124 electrically insulates the conductive sheets 122 and is combined with the conductive sheets 122. The controller 130 is electrically connected to the touch-sensing module 120 to identify a touch-sensing event on the conductive sheets 122.

The electronic apparatus 100 may use the conductive sheets 122 of the touch-sensing module 120 as an element for inputting a command. The touch-sensing module 120 is embedded at a side edge of the housing 110, for example. The conductive sheets 122 are respectively electrically connected with the controller 130. For example, when a finger of the user approaches or contacts the conductive sheets 122, a capacitance among the conductive sheets 122 may vary. The controller 130 is capable of identifying a location of occurrence of a touch-sensing event according to a capacitance variance, such that the electronic apparatus 100 may generate a feedback accordingly. The conductive sheets 122 of this embodiment may replace a mechanical button as an input element, such as a volume-control key or a power switch.

In this embodiment, a material of the housing 110 and the conductive sheets 122 is metal, for example. To avoid electrical connection between the housing 110 and the conductive sheets 122, the insulation material 124 is disposed between the housing 110 and the conductive sheets 122 for electrical insulation. Using the metallic conductive sheets 122 with the metallic housing 110 improves a consistency of the electronic apparatus 100 in appearance, i.e. the full-metallic housing 110 having the touch-sensing module 120.

In this embodiment, a material of the insulating material 124 is plastic, for example. Before the conductive sheets 122 are disposed on the electronic apparatus 100 as a touch-sensing input element, an opening is disposed on the housing 110 and the conductive sheets 122 and the insulation material 124 of the touch-sensing module 120 are disposed in the opening, such that the conductive sheets 122 are integrated with the housing 110 through the insulation material 124. The conductive sheets 122 and the insulation material 124 are disposed in the housing 110 with a manufacture process of insert-molding, for example. The conductive sheets 122 are disposed in the opening and fixed with a mold. Then the plastic insulation material 124 fills a space between the conductive sheets 122 and the housing 110 to separate the conductive sheets 122 and the housing 110 and prevent the conductive sheets 122 from being conducted with the metallic housing 110. However, the application does not impose a limitation that the insulation material 124 and the conductive sheets 122 are disposed in the housing 110 with the manufacture process of insert-molding.

Below describes a design and touch-sensing of the conductive sheets 122. FIG. 2B is a schematic view illustrating occurrence of a touch-sensing event in the conductive sheets of FIG. 2A. Referring to FIGS. 2A and 2B again, in this embodiment, a number of the conductive sheets 122 of the touch-sensing module 120 is two. The conductive sheets 122 are triangular, and the two conductive sheets 122 collectively form a quadrilateral sensing area. When the touch-sensing event occurs, the controller 130 senses the capacitance variance of the conductive sheets 122 to determine a touched location.

More specifically, in FIG. 2B, the conductive sheets 122 include a first conductive sheet 122a and a second conductive sheet 122b, for example. The first conductive sheet 122a and the second conductive sheet 122b have an identical appearance, but are disposed oppositely to form a rectangular-like sensing area. The insulating material 124 is disposed between the conductive sheets 122. The controller 130 respectively connects to the conductive sheets 122 via a plurality of connecting lines 132, so as to independently sense a capacitance variance of each of the conductive sheets 122.

When the finger of the user approaches the conductive sheets, a first coupling area is formed at the first conductive sheet 122a, and a second coupling area is formed at the second conductive sheet 122b. Since the first coupling area and the second coupling area are different, a capacitance variance generated in the first conductive sheet 122a and a capacitance variance generated in the second conductive sheet 122b are different. Therefore, the controller 130 is allowed to determine a location of the touched point according to the capacitance variances.

When the finger of the user touches different areas of the touch-sensing module 120, such as an area A and an area B in FIG. 2B, capacitances sensed by the first conductive sheet 122a and the second conductive sheets 122b may differ according to different locations being touched. For example, when the finger of the user touches the area A, the capacitances sensed by the first conductive sheet 122a and the second conductive sheet 122b are respectively C-Aa and C-Ab. When the finger of the user touches the area B, the capacitances sensed by the first conductive sheet 122a and the second conductive sheet 122b are respectively C-Ba and C-Bb.

In other words, when the finger of the user respectively touches the area A and the area B, the capacitance C-Aa sensed by the first conductive sheet 122a is different from the capacitance C-Ba sensed by the first conductive sheet 122a. Therefore, the touch-sensing module 120 may determine the location of the finger according to the different capacitances. Similarly, the second conductive sheet 122b operates in accordance with the same principle.

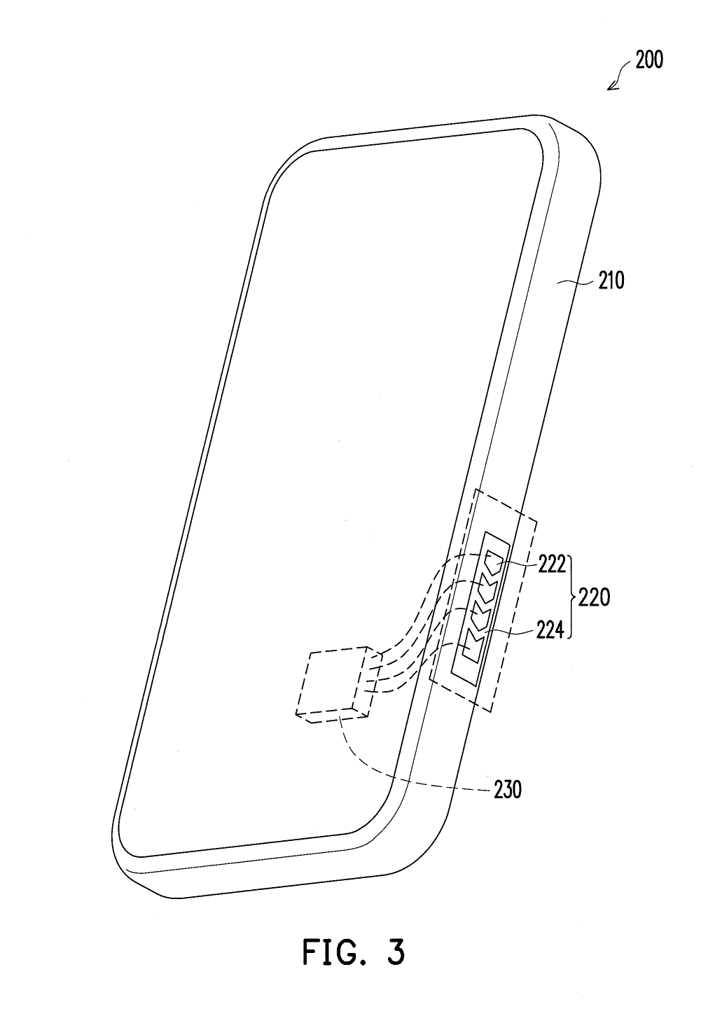

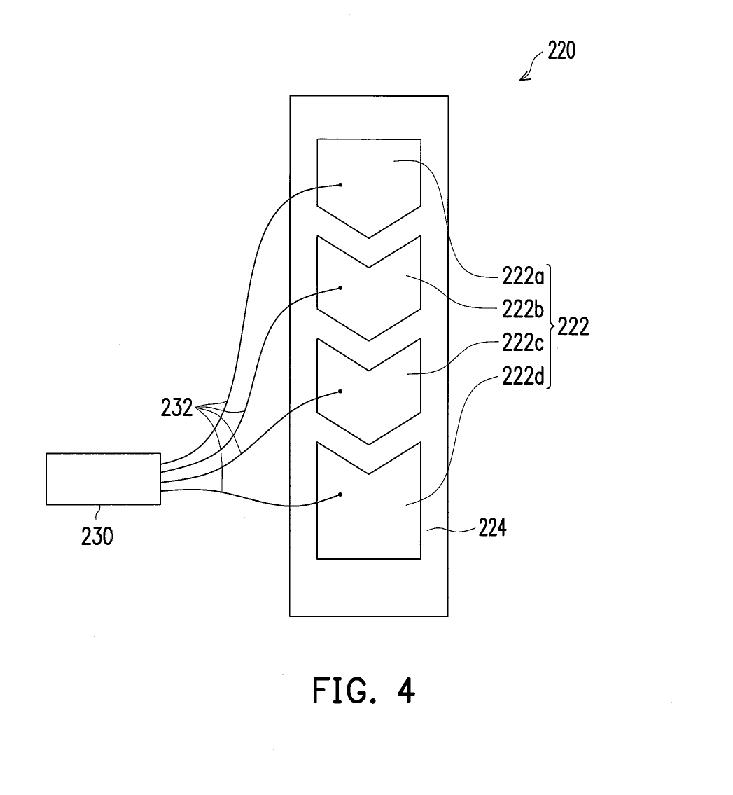

FIG. 3 is a schematic view illustrating an electronic apparatus according to another embodiment of the application. FIG. 4 is a partially enlarged view of the electronic apparatus of FIG. 3. Referring to FIGS. 3 and 4, in this embodiment, a housing 210 of an electronic apparatus 200 are also embedded with a touch-sensing module 220 formed of a plurality of conductive sheets 222 and an insulation material 224. In addition, a number of the conductive sheets 222 is four. The four conductive sheets 222 are arranged in a row to collectively form a quadrilateral sensing area. When a touch-sensing event occurs, a controller 230 senses the conductive sheet 222 on which the touch-sensing event occurs.

In this embodiment, the conductive sheets 222 include the first conductive sheet 222a, the second conductive sheet 222b, the third conductive sheet 222c, and the fourth conductive sheet 222d, for example. The four conductive sheets 222 are arranged in a row sequentially, and not all of the conductive sheets 222 have an identical appearance. The conductive sheets 222 form a quadrilateral-like sensing area. Appearances of the conductive sheets 222 may differ as an appearance of the electronic apparatus 200 differs. The application is not limited thereto. The insulation material 224 between the conductive sheets 222 may allow the controller 230 to independently sense a capacitance variance of each of the conductive sheets 222.

When the finger of the user approaches the conductive sheets 222, at least one of the conductive sheets 222 senses and generates capacitance. The controller 230 may obtain the capacitance variance on each of the conductive sheets 222 according to connecting lines 232 electrically connected with the first conductive sheet 222a, the second conductive sheet 222b, the third conductive sheet 222c, and the fourth conductive sheet 222d, so as to determine a location at which the touch-sensing event occurs.

In view of the foregoing, the housing of the electronic apparatus of the application is embedded with the touch-sensing module. The touch-sensing module is formed of the plurality of conductive sheets separated from each other and the insulation material. The conductive sheets are electrically insulated from each other and are respectively electrically connected with the controller. The conductive sheets may have different shapes and configurations according to different design needs. In addition, the conductive sheets form a sensing area in the electronic apparatus. When the touch-sensing event occurs, such as the finger of the user approaches or touches the conductive sheets, the controller is capable of identifying the touched position on the conductive sheets, so as to control the electronic apparatus. The conductive sheets in this application may replace the button as an input element. In addition, due to the metallic material of the conductive sheets, the conductive sheets have a metallic texture, and the appearance of the electronic apparatus is improved.

It will be apparent to those skilled in the art that various modifications and variations can be made to the structure of the disclosed embodiments without departing from the scope or spirit of the application. In view of the foregoing, it is intended that the application cover modifications and variations of this application provided they fall within the scope of the following claims and their equivalents.

What is claimed is:

1. An electronic apparatus, comprising:
a housing;
a touch-sensing module, embedded in the housing, the touch-sensing module comprising:
a plurality of conductive sheets;
an insulation material, electrically insulating the conductive sheets and is combined with the conductive sheets; and
a controller, electrically connected with the touch-sensing module to identify a touch-sensing event occurring on the conductive sheets.

2. The electronic apparatus as claimed in claim 1, wherein a material of the housing is metal, and the housing is insulated from the conductive sheets with the insulation material.

3. The electronic apparatus as claimed in claim 2, wherein a material of the conductive sheets is metal, and a material of the insulation material is plastic.

4. The electronic apparatus as claimed in claim 2, wherein the conductive sheets are integrated with the housing through the insulation material.

5. The electronic apparatus as claimed in claim 1, wherein a number of the conductive sheets is two, each of the conductive sheets is triangular, and the conductive sheets collectively form a quadrilateral sensing area.

6. The electronic apparatus as claimed in claim 1, wherein a number of the conductive sheets is four, the conductive sheets are arranged in a row, and the conductive sheets collectively form a quadrilateral sensing area.

7. The electronic apparatus as claimed in claim 1, wherein the touch-sensing module is embedded at a side edge of the housing.
